(19) United States
(12) Patent Application Publication
(10) Pub. No.: US 2015/0264809 A1
(43) Pub. Date: Sep. 17, 2015

(54) WIRING SUBSTRATE AND SEMICONDUCTOR DEVICE USING THE SAME

(71) Applicant: KABUSHIKI KAISHA TOSHIBA, Tokyo (JP)

(72) Inventors: Masayuki AOYAMA, Kanagawa Yokohama (JP); Atsushi WATANABE, Kanagawa Yokohama (JP)

(21) Appl. No.: 14/475,209

(22) Filed: Sep. 2, 2014

(30) Foreign Application Priority Data
Mar. 11, 2014 (JP) 2014-047543

(51) Int. Cl. H05K 1/11; H01L 23/31; H05K 3/24; H05K 1/02; H05K 3/06; H01L 23/00; H01L 23/498

(52) U.S. Cl. CPC H05K 1/111; H01L 24/49; H01L 23/3107; H01L 23/49822; H05K 1/0284; H05K 3/061; H05K 3/24; H01L 2924/2064

(57) ABSTRACT

According to one embodiment, a wiring substrate includes a second wiring layer, including a plurality of metal lands provided on a second surface of an insulating base material, and an insulating layer formed on the second surface of the insulating base material and including openings exposing the plurality of metal lands. The metal land includes a center portion with a first height and an outer peripheral portion with a second height lower than the first height, which is provided at least about the periphery of the insulating base. The openings expose the metal lands, such that the center portion of the metal land is exposed and at least a portion of the outer peripheral portion of the metal land is covered with the insulating layer.

### CROSS-REFERENCE TO RELATED APPLICATION

This application is based upon and claims the benefit of priority from Japanese Patent Application No. 2014-047543, filed Mar. 11, 2014, the entire contents of which are incorporated herein by reference.

### FIELD

Embodiments described herein generally relate to a wiring substrate and a semiconductor device using the same.

### BACKGROUND

As a typical structure of a semiconductor package, there has been known a package structure in which a semiconductor chip is mounted on one surface of a wiring substrate and an external connection terminal is provided on the other surface of the wiring substrate: for example, Land Grid Array (LGA) and Ball Grid Array (BGA) structures. A wiring substrate used in the LGA and the BGA structures includes, for example, an insulating base material, metal lands provided on one surface of the insulating base material, and a solder resist layer formed to cover a wiring layer including the metal lands. The solder resist is provided with openings extending therethrough for exposing each metal land through the openings in the solder resist layer. The LGA package uses a metal land, i.e., a planer electrode or contact structure, as the external connection terminal of the device. The BGA package is provided with solder balls on the metal lands as the external connection terminal of the device.

A wiring substrate for use in the LGA package is generally provided with the solder resist layer openings, each of which has a diameter larger than a land diameter in order to expose the whole width of a surface of an underlying metal land. When the LGA package using this wiring substrate is subjected to a heat cycle test, cracks may occur which extend from the opening in the solder resist layer adjacent the metal land and toward an insulating base material. On the other hand, a wiring substrate for use in a BGA package is provided with each solder resist layer opening configured so that the resist at the edge of the opening may cover the edge of the metal land to expose a portion of the land surface therebetween. The wiring substrate with these opening structures may restrain the generation of the above described crack; however, the wiring substrate impairs planarity of the surface having the metal lands, i.e., they extend above the resist layer, and therefore, this structure is not suitable for the LGA package.

### DESCRIPTION OF THE DRAWINGS

FIG. 1 is a view illustrating a semiconductor device according to an embodiment.

FIGS. 2A and 2B are an enlarged view illustrating a part of a first example of a wiring substrate for use in the semiconductor device illustrated in FIG. 1.

FIGS. 3A and 3B are an enlarged view illustrating a part of a second example of a wiring substrate for use in the semiconductor device illustrated in FIG. 1.

FIGS. 4A and 4B are an enlarged view illustrating a part of a third example of a wiring substrate for use in the semiconductor device illustrated in FIG. 1.

FIGS. 5A, 5B, 5C, and 5D are a view illustrating a process of manufacturing the wiring substrate illustrated in FIG. 1.

### DETAILED DESCRIPTION

In general, according to an embodiment, a wiring substrate includes an insulating base material having a first surface and a second surface, a first wiring layer provided on the first surface of the insulating base material, a second wiring layer provided on the second surface of the insulating base material which includes a plurality of metal lands, and an insulating layer, formed on the second surface of the insulating base material, including openings exposing the plural metal lands. Of the plural metal lands, at least each of the metal lands provided about the periphery of an area where a semiconductor chip is mounted on the insulating base includes a center portion with a first height and an outer peripheral portion with a second height lower than the first height. The openings in the insulating layer provided about the periphery of an area where a semiconductor chip is to be mounted on the insulating base, expose at least the center portion of the metal lands therein, such that at least a portion of the outer peripheral portion of the metal lands is covered with the insulating layer.

A semiconductor device according to one embodiment includes the wiring substrate according to the embodiment, a semiconductor chip which is mounted on the first surface of the wiring substrate and electrically connected to the first wiring layer, and a sealing resin layer which is provided on the first surface of the wiring substrate to seal the semiconductor chip.

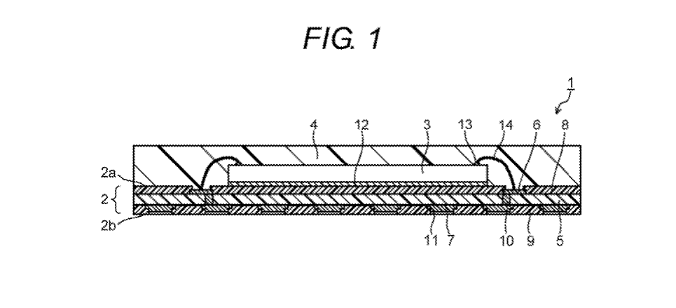

Hereinafter, a wiring substrate and a semiconductor device according to one embodiment will be described with reference to the drawings. FIG. 1 is a cross-sectional view illustrating a semiconductor device according to the embodiment. A semiconductor device 1 illustrated in FIG. 1 includes a wiring substrate 2, a semiconductor chip 3 mounted on a first surface 2a of the wiring substrate 2, and a sealing resin layer 4 for sealing the semiconductor chip 3. Here, a vertical direction in the following description means that the first surface 2a of the wiring substrate 2 on which the semiconductor chip 3 is mounted is defined to be an upper direction with respect to the semiconductor device 1 of drawing FIG. 1.

The wiring substrate 2 includes an insulating resin material made of glass-epoxy resin as an insulating base material 5. A first wiring layer, including internal connection terminals 6 that are a portion thereof for electrically connecting to the semiconductor chip 3, is provided on the upper surface (first surface) of the insulating base material 5. A second wiring layer, which includes circular shaped metal lands 7, is provided on the lower surface (second surface) of the insulating base material 5. The metal lands 7 serve as a connection portion for electrically connecting the semiconductor device 1 to an external device, or an external connection terminal. The metal lands 7 form at least a portion of the second wiring layer provided on the lower surface of the insulating base material 5.

A solder resist layer 8 is formed as an insulating layer on the first surface 2a having the first wiring layer of the wiring substrate 2. Similarly, a solder resist layer 9 is formed as an insulating layer on a second surface 2b having the second wiring layer of the wiring substrate 2. The first wiring layer and the second wiring layer are electrically connected together through a via 10 formed to penetrate the insulating base material 5. The solder resist layer 9 provided on the lower surface of the insulating base material 5 includes openings 11 extending therethrough through which the underlying metal land 7 is exposed. The shape of the metal land 7 and the opening 11 will be described further herein.

Referring again to FIG. 1, the semiconductor chip 3 is mounted on the first surface 2a of the wiring substrate 2. The semiconductor chip 3 is bonded to the first surface 2a of the wiring substrate 2 through a bonding layer 12. An electrode pad 13 provided on the upper surface of the semiconductor chip 3 is electrically connected to the internal connection terminal 6 of the wiring substrate 2 via a bonding wire 14 such as a Au wire. The sealing resin layer 4 for sealing the semiconductor chip 3 and the bonding wire 14 is provided on the first surface 2a of the wiring substrate 2. Thus, the semiconductor device 1 illustrated in FIG. 1 forms an LGA package with the metal lands 7 used as the external connection terminals.

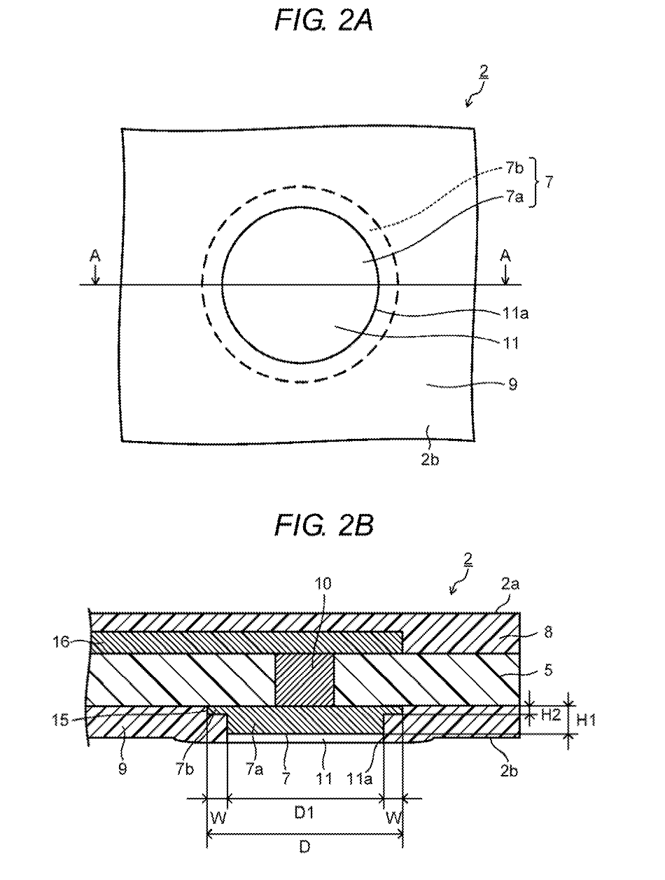

The shape of the metal land 7 provided on the lower surface of the insulating base material 5 and the shape of the openings 11 in the insulating layer for exposing the metal land 7 will be described with reference to FIGS. 2A and 2B to 4A and 4B. FIGS. 2A and 2B to 4A and 4B are enlarged views illustrating a part of the first to the third examples of the wiring substrate 2; each figure A is a bottom view of the wiring substrate 2 and each figure B is a cross-sectional view taken along the line A-A of each figure A. As illustrated in FIGS. 2A and 2B to 4A and 4B, the metal land 7 that forms at least a portion of a second wiring layer 15 provided on the lower surface of the insulating base material 5 includes a center portion 7a having a height H1 and a diameter D1 and an outer peripheral portion 7b having a height H2, an outer diameter D and a width W. The second wiring layer 15, including the metal land 7, is electrically connected to a first wiring layer 16 provided on the upper surface of the insulating base material 5 through a via 10.

The center portion 7a of the metal land 7 occupies a large portion of the opening 11 in the solder resist layer 9 (insulating layer) in the center of the opening 11 and serves as the external connection terminal; it has the diameter D1 of, for example, approximately 300 to 800 μm, similar to the whole diameter of the conventional metal land without a step. The height H1 of the center portion 7a depends on the thickness of a Cu film used in the manufacturing process of the wiring substrate 2; it is, for example, approximately 25 to 50 μm. The outer peripheral portion 7b of the metal land 7 is formed continuously with the center portion 7a at the outer periphery of the center portion 7a, having a height H2 lower than the height H1 of the center portion 7a. In other words, the metal land 7 is formed in a shape with a step provided in the outer peripheral portion, with the center portion 7a serving as the external connection terminal and the thin outer peripheral portion 7b provided continuously about the outer periphery of the center portion 7a. The respective heights H1 and H2 of the center portion 7a and the outer peripheral portion 7b indicate a height from the lower surface of the insulating base material 5.

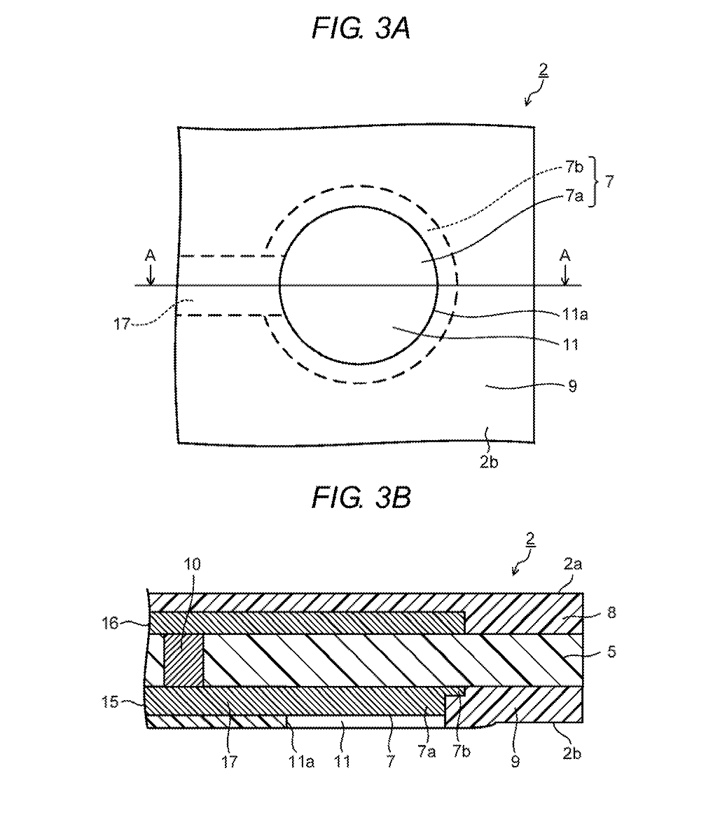

FIGS. 2A and 2B illustrate the metal land 7 with the outer peripheral portion 7b provided around the whole periphery of the center portion 7a. The shape of the metal land 7 is not restricted to this construct. For example, as illustrated in FIGS. 3A and 3B, when a wiring layer 17 formed on the lower surface of the insulating base material 5 is connected to the metal land 7 (center portion 7a), the outer peripheral portion 7b is provided in the outer periphery of the center portion 7a excluding the connection portion of the wiring layer 17. Thus, the outer peripheral portion 7b may be provided about the whole outer periphery of the center portion 7a, or only about a portion of the outer periphery of the center portion 7a.

The opening 11 in the solder resist layer 9 is provided to bare, i.e., expose, the whole surface of the center portion 7a of the metal land 7. While exposing the center portion 7a, the opening 11 has an opening end 11a provided on the outer peripheral portion 7b so that the outer peripheral portion 7b may be covered with the solder resist layer 9. In other words, the opening 11 is designed to expose the center portion 7a serving as the external connection terminal and simultaneously cover, with the solder resist layer 9, at least a portion of the outer peripheral portion 7b which is lower than the center portion 7a. The opening 11 is provided so that the circumferential ledge of the resist layer 9 at the opening 11 is positioned on the outer peripheral portion 7b. As illustrated in FIGS. 3A and 3B, when the outer peripheral portion 7b is formed along a portion of the outer periphery of the center portion 7a, a portion of the resist 9 at the ledge is positioned on (over) the outer peripheral portion 7b.

As mentioned above, when the opening in the insulating layer (solder resist layer 9) simply has a diameter larger than the land diameter, the insulating base material formed of a compound material including a glass cloth type material having low mechanical strength formed of an insulating resin is exposed in the vicinity of the opening portion; therefore, when the semiconductor device is subjected to a heat cycle test of, for example, −50° C. to 125° C.×1000 cycles, there may occur a crack starting from the opening end of the insulating base material and the crack generated in the insulating base material may reach the wiring layer on the upper side of the insulating base material, which may cause an electrical failure of the wiring substrate. In view of this, by covering the outer peripheral portion 7b of the metal land 7 with the solder resist layer 9, the insulating base material 5 positioned in the vicinity of the opening 11 may be prevented from being exposed while exposing the whole surface of the center portion 7a of the metal land 7 serving as the external connection terminal. Therefore, a crack may be restrained from occurring in the base material during a heat cycle test.

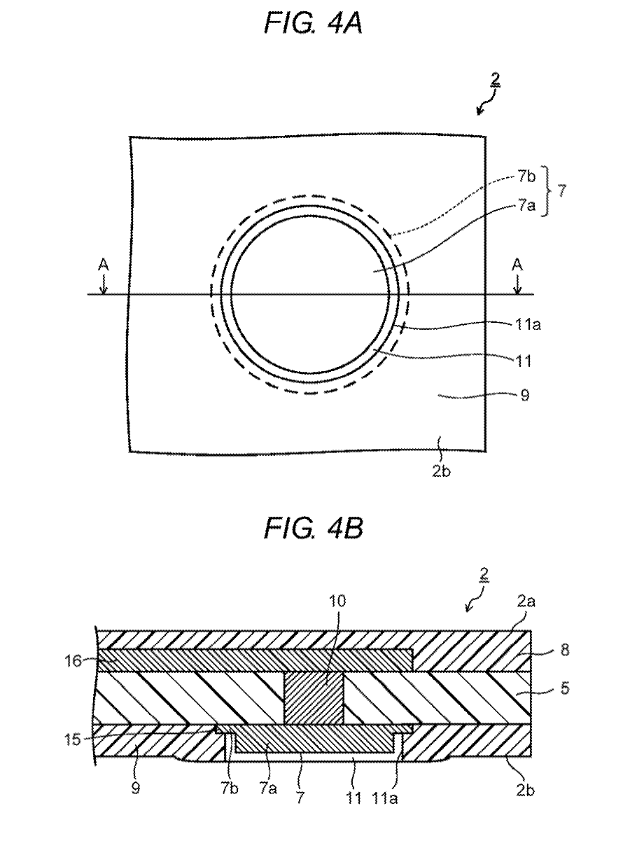

The diameter (opening diameter) of the opening 11 should be not less than the diameter D1 (actual land diameter) of the center portion 7a of a land and less than a diameter D of the whole metal land 7 including the outer peripheral portion 7b, such that the whole surface of the center portion 7a serving as the external connection terminal may be exposed through the opening 11 while the outer peripheral portion 7b may be covered with the solder resist layer 9. FIG. 2 illustrates the configuration in which the diameter of the opening 11 is substantially equal to the diameter D1 of the center portion 7a; however, the opening diameter, as compared to the diameter of the center portion 7a, is not restricted to this. For example, the opening 11 corresponding to the ledge configured to overhang as illustrated in FIGS. 4A and 4B may be used.

FIGS. 4A and 4B illustrate the opening 11 having such a diameter that the ledge of the resist layer 9 may be positioned to extend inwardly of the metal land 7 to approximately the middle of the outer peripheral portion 7b thereof. In this case, even when an error occurs within the tolerance in the exposure and development process for forming the opening 11 in the solder resist layer 9, the ledge may be assuredly positioned to overlie at least a portion of the outer peripheral portion 7b. However, when the diameter of the opening 11 is made too large, at least a portion of the opening end 11a becomes deviated from the outer peripheral portion 7b and the adjacent insulating base material 5 may be exposed. The diameter of the opening 11 may be chosen taking this into consideration. Alternatively, when the width W of the outer peripheral portion 7b is too narrow, since the position of the opening end 11a may be different than that of the outer peripheral portion 7b, the width W of the outer peripheral portion 7b is preferably set at 50 μm and more. However, when the width W of the outer peripheral portion 7b is set too wide, the density of the metal lands 7 on the wiring substrate 2 is lowered, which may increase the size of the wiring substrate 2 needed to accommodate the lands; therefore, the width W of the outer peripheral portion 7b is preferably 100 μm and less.

Further, the position of the metal land 7 covered with the solder resist layer 9 is set at the outer peripheral portion 7b to have the height H2 extending from the insulating base 5 lower than the height H1 of the center portion 7a extending from the insulating base 5, and therefore, the extent of the solder resist layer 9 covering the metal land 7 may be smaller than in previous devices. When the end portion of a metal land 7 not having the outer peripheral portion 7b is covered with a solder resist layer, the outer surface thereof extends outwardly of the semiconductor device 1, and therefore the planarity of the outer surface of the resin layer 9 of the wiring substrate suffers. The wiring substrate 2 according to the embodiment is thus configured to prevent generation of a crack caused by exposure of the insulating base material 5 and to reduce deterioration of the planarity of the lower surface 2b of solder resist layer 9 of the wiring substrate 2.

It is preferable that the height H2 of the outer peripheral portion 7b is set as low as possible in consideration of minimizing interruptions in the planarity of the second surface (lower surface) 2b of the wiring substrate 2. For example, in consideration of connecting the metal land 7 (center portion 7a) to a terminal of an external device through solder, it is preferable that the height H2 of the outer peripheral portion 7b is set not more than ½ of the height H1 of the center portion 7a (H2≦0.5H1). However, when the height H2 of the outer peripheral portion 7b is too small, a portion of the insulating base material 5 may be exposed depending on the etching accuracy in the process of forming the metal lands 7 described later herein. Therefore, the height H2 of the outer peripheral portion 7b is preferably 10 μm or more.

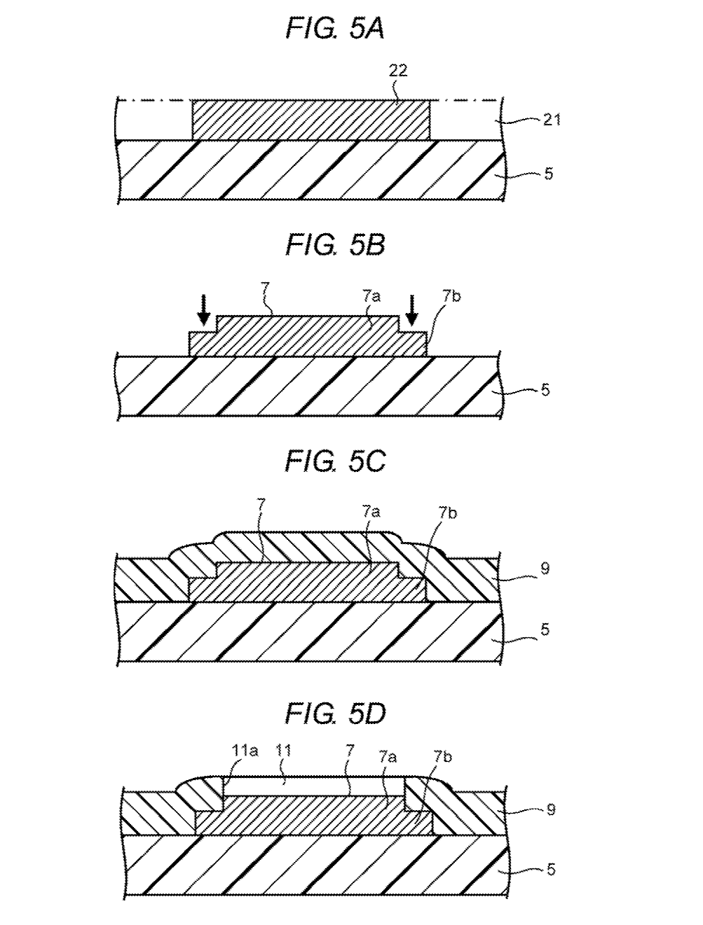

The metal land 7 including the center portion 7a and the outer peripheral portion 7b mentioned above is manufactured, for example, as follows. At first, as illustrated in FIG. 5A, a metal layer 21 made of a Cu film which is formed on the insulating base material 5 is subjected to the patterning process including the exposure and development of a resist layer and etching of the copper exposed through openings in the resist, hence to form a metal pattern 22 having a diameter corresponding to the whole diameter D of the metal land 7 including the outer peripheral portion 7b. Then, as illustrated in FIG. 5B, a resist (not illustrated) corresponding to the center portion 7a is formed on the metal pattern 22 and a portion corresponding to the outer peripheral portion 7b is selectively etched while the center portion is protected from the etchant by the resist. Accordingly, the metal land 7 including the center portion 7a and the outer peripheral portion 7b lower than the center portion 7a are formed. Here, the height H2 of the outer peripheral portion 7b is preferably set in the above mentioned range, in order to prevent exposure of a portion of the insulating base material 5 and to limit deterioration of the planarity of the second surface (lower surface) 2b of the wiring substrate 2.

The opening 11 for exposing the center portion 7a of the metal land 7 is formed, for example, as follows. At first, as illustrated in FIG. 5C, the solder resist layer 9 is formed to cover the metal land 7 on the insulating base material 5. Then, as illustrated in FIG. 5D, the solder resist layer 9 is subjected to the exposure and development process, hence to form the opening 11. Here, by setting the diameter of the opening 11 (opening diameter) so that the opening end 11a may be positioned on the outer peripheral portion 7b, there may be formed a structure where the opening 11 exposes the center portion 7a while covering at least a portion of the outer peripheral portion 7b with the solder resist layer 9.

Further, it is preferable that the diameter of the opening 11 and the width W of the outer peripheral portion 7b is set relative to one another in the above mentioned range in order to prevent the ledge of the opening 11 from lying over the center portion 7a and the opening end 11a from deviating from, i.e., extending radially or circumferentially outwardly of, the radial span of the outer peripheral portion 7b. The center portion 7a of the metal land 7 exposed through the opening 11 is preferably formed to have a uniform height H1 across the whole surface thereof. In prior art systems when the center portion 7a of the metal land 7 exposed in the opening 11 has a recessed portion in the opening 11, there remains residue from the solder resist layer 9 on the surface of the center portion 7a of the metal land 7 when forming the opening 11, which if remaining will cause an increase in resistance in an electrical connection to the outside.

A crack in the insulating base material 5 starting from the opening 11 occurring during a heat cycle test easily occurs in the metal lands arranged in a matrix shape on the second surface 2b of the wiring substrate 2, especially in the metal lands provided along the periphery of the area where the semiconductor chip 3 is mounted. Therefore, the metal land 7 including the center portion 7a and the outer peripheral portion 7b may need to be used for the metal lands positioned on the periphery of the chip-mounted area, of the wiring layer patterns including a plurality of the metal lands formed corresponding to the position of the semiconductor chip 3 to be mounted thereon. Specifically, the metal land 7 having the center portion 7a and the outer peripheral portion 7b may be used for the metal lands positioned in the outermost portion of, i.e., along the perimeter of the insulating base material 5, on the second surface 2b of the wiring substrate 2 in the semiconductor device 1 illustrated in FIG. 1 or those metal lands positioned in the outermost portion of, and in one or two rows of lands inwardly positioned from the outermost row of lands 7. The remaining metal lands which are exposed through openings may have an opening diameter larger than the land diameter.

The opening 11 illustrated in FIGS. 3A and 3B may be applied only to the metal lands 7 which have the wiring layer 17 connected to the center portion 7a of the land 7. Accordingly, a combination of the metal lands 7 and the openings 11 illustrated in FIGS. 2A and 2B and FIGS. 4A and 4B and a combination of the opening 11 and the metal land 7 illustrated in FIGS. 3A and 3B may be combined on a single semiconductor device 1. Further, a combination of the previously used configurations of metal lands without a step in an opening in the solder resist layer 9 which has a diameter greater than the metal land diameter may also be used in combination with one or more of the opening 11 and land 7 configurations shown in FIGS. 2 to 4, where the position of such lands on the insulating base 5 does not result in cracking of portions of the semiconductor device 1 during a heat cycle test. As mentioned above, a combination of the metal land 7 and the opening 11 may be properly applied depending on the formed position of a metal land and the shape of a wiring layer attached to the metal land, and a plurality of combinations thereof may be used within one semiconductor device 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A wiring substrate comprising:
an insulating base material having a first surface and a second surface;
a first wiring layer provided on the first surface of the insulating base material;
a second wiring layer provided on the second surface of the insulating base material and including a plurality of metal lands; and
an insulating layer, formed on the second surface of the insulating base material, including openings therein exposing the plural metal lands, wherein
of the plural metal lands, at least each of the metal lands provided about the periphery of an area where a semiconductor chip is to be mounted on the insulating base includes a center portion with a first height and an outer peripheral portion with a second height lower than the first height, and
the openings in the insulating layer provided about the periphery of an area where a semiconductor chip is to be mounted on the insulating base, expose at least the center portion of the metal lands therein, such that at least a portion of the outer peripheral portion of the metal lands is covered with the insulating layer.

2. The wiring substrate according to claim 1, wherein
the portion of the insulating layer covering the outer peripheral portion of the metal land extends about an entire outer periphery of the center portion of the metal land.

3. The wiring substrate according to claim 1, wherein
a height of the outer peripheral portion of the metal land is equal to one-half of a height of the center portion of the metal land, or less, and is at least 10 μm thick.

4. The wiring substrate according to claim 1, wherein
the insulating layer is a solder resist layer.

5. The wiring substrate according to claim 1, wherein the insulating layer extends over the outer peripheral portion of the metal land, but is spaced from the center portion of the metal land.

6. The wiring substrate according to claim 5, wherein the plural metal lands further include at least one metal land in which the insulating layer extends over the outer peripheral portion of the metal land, and also contacts the center portion of the metal land.

7. The wiring substrate according to claim 1, wherein the insulating layer extends over the outer peripheral portion of the metal land, and also contacts the center portion of the metal land.

8. The wiring substrate according to claim 1, wherein the plural metal lands further include at least one metal land, located inwardly of the periphery of an area where a semiconductor chip is to be mounted on the insulating base and positioned within an opening in the insulating layer wherein a gap is maintained between the perimeter of the outer portion of the metal land and the adjacent surfaces of the insulating layer.

9. A semiconductor device comprising:
an insulating base material having a first surface and a second surface;
a first wiring layer provided on the first surface of the insulating base material;
a second wiring layer provided on the second surface of the insulating base material and including a plurality of metal lands; and
an insulating layer, formed on the second surface of the insulating base material, including openings therein within which at least a portion of each of the plural metal lands is exposed, wherein
of the plural metal lands, at least each of the metal lands provided about the periphery of the insulating base includes a center portion with a first height and an outer peripheral portion with a second height lower than the first height, and
the openings in the insulating layer provided about the periphery of the insulating base, expose at least the center portion of the metal lands therein, such that at least a portion of the outer peripheral portion of the metal lands is covered with the insulating layer,
a semiconductor chip that is mounted on the first surface of the insulating base material including the first wiring layer and electrically connected to the first wiring layer; and
a sealing resin layer provided on the first surface of the insulating base material to seal the semiconductor chip, wherein
the plural metal lands are used as external connection terminals of the semiconductor device.

10. The semiconductor device of claim 9, wherein
the portion of the insulating layer overlying the outer peripheral portion of the metal land extends about the entire outer periphery of the center portion of the metal land.

11. The semiconductor device of claim 9, wherein
a height of the outer peripheral portion of the metal land is equal to one-half of the height of the center portion of the metal land, or less, and is at least 10 μm thick.

12. The semiconductor device of claim 9, wherein
the insulating layer is a solder resist layer.

13. The semiconductor device of claim 9, wherein the insulating layer extends over the outer peripheral portion of the metal land, but is spaced from the center portion of the metal land.

14. The semiconductor device of claim 13, wherein the plural metal lands further include at least one metal land in which the insulating layer extends over the outer peripheral portion of the metal land, and also contacts the center portion of the metal land.

15. The semiconductor device of claim 9, wherein the insulating layer extends over the outer peripheral portion of the metal land, and also contacts the center portion of the metal land.

16. The semiconductor device of claim 9, wherein the plural metal lands further include at least one metal land, located inwardly of the periphery of the insulating base and positioned within an opening in the insulating layer wherein a gap is maintained between the perimeter of the outer portion of the metal land and the adjacent surfaces of the insulating layer.

17. A method of forming a metal land contact on an insulating substrate, comprising:
providing a metal layer on the insulating substrate;
providing an etch resistant layer on selected portions of the metal layer while leaving exposed other portions thereof;
etching away the exposed metal layer leaving a preform of a metal land contact in place on the substrate;
forming an etch resistant layer over a central portion of the metal land contact while leaving the perimeter of the metal land contact exposed;
etching the exposed perimeter of the metal land contact to leave a recessed portion thereof adjacent the central portion thereof;
covering the metal land contact having the recessed portion thereof adjacent the central portion thereof and the adjacent surfaces of the insulating substrate with an insulating layer;
exposing the portion of the insulating layer overlying the central portion of the metal land selectively; and
removing the exposed portion of the insulating layer overlying the central portion of the metal land and leaving in place at least a portion of the insulating layer overlying at least a portion of the recessed portion of the metal land.

18. The method of claim 17, wherein:
forming an etch resistant layer over a central portion of the metal land contact while leaving the perimeter of the metal land contact exposed;
etching the exposed perimeter of the metal land contact to leave a recessed portion thereof adjacent the central portion thereof;
covering the metal land contact having the recessed portion thereof adjacent the central portion thereof and the adjacent surfaces of the insulating substrate with an insulating layer;
exposing the portion of the insulating layer overlying the central portion of the metal land selectively; and
removing the exposed portion of the insulating layer overlying the central portion of the metal land and leaving in place at least a portion of the insulating layer overlying at least a portion of the recessed portion of the metal land;
are performed on the metal land located outwardly of the perimeter of the portion of the insulating substrate on which a semiconductor device is to be mounted.

19. The method of claim 18, wherein, in the region located inwardly of the periphery of the portion of the insulating substrate on which a semiconductor device is to be mounted:
covering the metal land contact and the adjacent surfaces of the insulating substrate with the etch resistant layer;
exposing the portion of the insulating layer overlying the metal land and the adjacent surfaces of the insulating substrate; and
removing the exposed portion of the insulating layer overlying the metal land;
are performed.

20. The method of claim 19, wherein during removing the exposed portion of the insulating layer overlying the metal land, adjacent portions of the insulating substrate become exposed.
